(19) United States
(12) Patent Application Publication
(10) Pub. No.: US 2020/0339613 A1
(43) Pub. Date: Oct. 29, 2020

(54) MODIFIED PEROVSKITES AND PEROVSKITE LIKES AND USES THEREOF

(71) Applicant: KATHOLIEKE UNIVERSITEIT LEUVEN, Leuven (BE)

(72) Inventors: Johan Hofkens, Leuven (BE); Maarten Roeffaers, Leuven (BE); Haifeng Yuan, Leuven (BE); Julian Steele, Leuven (BE)

(73) Assignee: KATHOLIEKE UNIVERSITEIT LEUVEN, Leuven (BE)

(21) Appl. No.: 16/961,356

(22) PCT Filed: Jan. 14, 2019
(86) PCT No.: PCT/EP2019/050745

§ 371 Date: Jul. 10, 2020

Related U.S. Application Data
(60) Provisional application No. 62/616,851, filed on Jan. 12, 2018.

(51) Int. Cl. C07F 7/24; H01L 51/00; H01L 27/30

(52) U.S. Cl. CPC C07F 7/24; H01L 27/308; H01L 51/0027; H01L 51/0015

(57) ABSTRACT

Present invention concerns optical processing of materials comprising complex phase behaviour, such as perovskites for stabilizing the optically active phase of thin films of materials with complex phase behaviour, such as perovskites.

### BACKGROUND AND SUMMARY

### Background of the Invention

### A. Field of the Invention

Present invention concerns optical processing of materials comprising complex crystal phase behavior, such as metal halide perovskites for stabilizing the optically active phase of thin films of materials with complex phase behaviour, such as metal halide perovskites.

### B. Description of the Related Art

Organic-inorganic halide perovskites are emerging materials for next-generation optoelectronic applications such as photovoltaics, light emitting, photo-detection and X-ray/Gamma-ray detection. Their advantages include ease in solution-process, low fabrication cost and high energy conversion efficiency.

Nonetheless, the material instability to heat and moisture hinders their large-scale applications. The inorganic perovskite, CsPbI₃, has a suitable energy bandgap for efficient energy conversion, and is far more stable than its organic-inorganic counterparts. Doping cesium into the organic-inorganic perovskites can readily enhance the material stability and yield significant improvements in the device performance. Nevertheless, the polymorph phase behavior makes cesium lead iodide impossible to stay at its opto-electrically functional black phase at room temperature (near 25 Celsius degrees), thus making it challenging for device applications.

There is a need in the art to improve this problem of phase instability which is an object of present invention.

### SUMMARY OF THE INVENTION

The present invention solves the problems of the related art by providing a fast, low cost method of forming at ambient conditions a stable optically active phase material by subjecting an halide perovskite material to an illumination treatment that creates pattern grid structure or connected patterns, for instance in the forms of micron scale square blocks. This structure is form in particular at the locoregional illumination. The technical effect thereof is stabilization in the meaning that the nucleation rate is suppressed or that the phase transition processes in the enclosed material region are slowed down so that the newly created material is suitable for operationally or functionally been integrated in optoelectronic devices of the group consisting of photovoltaics, light emitters, photo-detection, X-ray detection, Gamma-ray detection, imaging sensors, and chemical sensors.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description. It is to be understood that both the foregoing general description and the following detailed description are exemplary and explanatory only and are not restrictive of the invention, as embodimented.

According to one embodiment of the invention a method of manufacture is provided which comprises subjecting a metal halide perovskite material to an irradiation treatment to form an at ambient condition stable optically active phase material.

The present invention also provides a method of manufacture which comprises subjecting a metal halide perovskite material to an irradiation treatment to form an at ambient condition stable optically active phase material, characterised in that an area of the metal halide perovskite material is locoregionally and in a pattern irradiated.

The object of the present invention is also a method of manufacture which comprises subjecting a metal halide perovskite material to an irradiation treatment to form an at ambient condition stable optically active phase material, characterised in that an area of the metal halide perovskite material is locoregionally and in a grid pattern irradiated.

The present invention also relates to a method of manufacture which comprises subjecting a metal halide perovskite material to an irradiation treatment to form an at ambient condition stable optically active phase material, whereby connected patterns are created onto the material and into the sub-surface of the material by locoregional irradiation.

The object of the present invention is also to provide a method of manufacture which comprises subjecting a metal halide perovskite material to an irradiation treatment to form an at ambient condition stable optically active phase material, whereby a grid structure is created sub-surface into the material by locoregional irradiation on an area of the material.

The object of the present invention is also to provide a method of manufacture which comprises subjecting a metal halide perovskite material to an irradiation treatment to form an at ambient condition stable optically active phase material, whereby a patterned locoregional material alteration is irradiated in the metal halide perovskite material to form the at ambient condition stable optically active phase material.

The object of the present invention is also to provide a method of manufacture which comprises subjecting a metal halide perovskite material to an irradiation treatment to form an at ambient condition stable optically active phase material, characterised in that the treatment is irradiating a grid pattern of material alteration on and into the metal halide perovskite material to form it in an at ambient condition stable optically active phase material.

The object of the present invention is also to provide a method of manufacture which comprises subjecting a metal halide perovskite material to an irradiation treatment to form an at ambient condition stable optically active phase material, characterised in that the treatment is irradiating a grid pattern of material alteration on a surface area and into its sub-surface of the metal halide perovskite material to form it in an at ambient condition stable optically active phase material.

The object of the present invention is also to provide a method of manufacture which comprises subjecting a metal halide perovskite material to an irradiation treatment to form an at ambient condition stable optically active phase material, whereby a pattern is created as micron scale square blocks.

The object of the present invention is also to provide a method of manufacture which comprises subjecting a metal halide perovskite material to an irradiation treatment to form an at ambient condition stable optically active phase material, whereby a grid pattern of barrels or cups is grafted in an area of the metal halide perovskite material. These barrels or cups may have a cube, tubular, cylindrical, discoidal, spherical, tabular, ellipsoidal, irregular or squared shape.

In order to enhance the formation of at ambient condition stable optically active phase material it is desirable that irradiation treatment is grafting or annealing upright partitions of material alterations through an area of the metal halide perovskite material so that an array of metal halide perovskite units, which are separated by said partitions, is formed. An at ambient condition stable optically active phase material is easily achieved, when the irradiation treatment is grafting or annealing upright partitions of material alterations through an area of a metal halide perovskite material so that an array of metal halide perovskite units separated by said partitions is formed. In a particular embodiment this achieved by an irradiation treatment which is grafting a grid of walls of material alterations in the metal halide perovskite material, whereby the walls upright from a plane of the metal halide perovskite material that is proximate to a base carrier material to that plane of said the metal halide perovskite material that is distal from the base carrier material. These walls of material alterations can be sloped. In accordance with the above-mentioned methods at ambient condition stable optically active phase material with complex phase behavior can be formed.

Usually one starts from a metal halide perovskite material in the form of a film or from a metal halide perovskite material has a shelf form, sheet form or a planar form so that one can put it with a large facer area under a irradiation means to irradiate a pattern.

Usually when used for photovoltaics, light emitting, photo-detection, X-ray detection, Gamma-ray detection, imaging sensors or chemical sensors applications the metal halide perovskite material will be a layer stacked on a carrier layer. In a particular embodiment of present invention, the metal halide perovskite material is fitted on or annealed to a carrier layer for instance a glass layer or an indium tin oxide functionalized glass layer or the metal halide perovskite material is spin coated on a substrate. It was observed that this provides the most stable optically active phase material when processed by irradiation according to the method of present invention.

For producing the at ambient condition stable optically active phase material of present invention in accordance with the method of manufacture of present invention the following metal halide perovskite material are suitable. For instance the material comprises AMX₃ compounds, whereby M is a metal ion such as Pb²⁺ and A is a cation such as methylammonium (MA+), formamidinium (FA+), cesium (Cs+), . . . and X is of the group consisting of fluoride (F⁻), chloride (Cl⁻), bromide (Br⁻), iodide (I⁻) and astatide (At⁻) and their mixed counterparts AₘA′A″ₙA₍₁₋ₘ₋ₙ₎MXₓX′_{y}X″_{(3-x-y)}MₘM′ₙM″₍₁₋ₘ₋ₙ₎AXₓX′_{y}X″_{(3-x-y)} and doped counterparts with manganese, tin, magnesium, potassium, sodium, rubidium and/or silver. Other such suitable materials are a material that comprises perovskite with CsPbX₃ (X=F, Cl, Br, I) compounds, a material that comprises perovskite with FAPbX₃ (X=Cl, Br, I) compounds, a material that comprises perovskite with CsPbI₃, FAPbI₃, MAPbI₃ or their mixed compounds to manufacture stable optical/optoelectrical active CsPbI₃ perovskite, FAPbI₃ perovskite or their mixed perovskites.

The method of irradiation in accordance with present invention can result in a material that is locoregional physically and/or chemically altered under irradiation.

Suitable metal halide perovskite are for instance metal halide perovskite that comprises inorganic cations, that comprises organic cations, that comprise a mixture of organic and inorganic cations.

In order to enhance the formation of at ambient condition stable optically active phase material it is desirable to have a metal halide perovskite comprised in a thin film.

Suitable irradiation treatments are all-optical irradiations for instance whereby the optical treatment is a scanning light beam, whereby the optical treatment is covering a large area illumination, whereby the optical treatment is by sample scanning, whereby the optical treatment is by focused single spot scanning, whereby the illumination is masked illumination, whereby the illumination is masked illumination to have certain locoregions on said material illuminated and other regions not or to illuminate a mask pattern on said treated material, whereby the illumination is minored laser illumination, whereby the mask has a plurality of illumination apertures through which light of the illumination elements is transmitted, whereby the optical treatment can take any wavelength absorbed by the metal halide perovskite material, whereby the optical treatment can take any coherence or whereby the optical treatment can take any polarization. Such optical treated zone on the material are at temperatures far below its phase transition temperature, for instance more than 50° C. thereunder, even more preferably more than 100° C. thereunder and yet more preferably more than 200° C. thereunder for instance when the metal halide perovskite material is CsPbI₃ and the optical treated zone on the material are at temperatures far below its phase transition temperature of 320 Celsius degree, for instance more than 50° C. thereunder, even more preferably more than 100° C. thereunder and yet more preferably more than 200° C. thereunder.

At ambient condition stable optically active phase material can be formed by the irradiation methods of present invention by that the metal halide perovskite materials are stabilized by that the nucleation rate is suppressed.

At ambient condition stable optically active phase material can be formed by the irradiation methods of present invention by that the metal halide perovskite materials are stabilized by that phase transition processes in the enclosed material region are slowed down. Subjecting the according to present invention irradiated materials to a treatment at a temperature below phase transition temperature will trigger the optically active perovskite to the non active phase transition.

According to one embodiment the invention concerns an at ambient condition stable optically active phase material, characterised in that it comprises metal halide perovskite material with a grid pattern of material alterations, for instance chemical or physical alterations.

According to one embodiment the invention also concerns an at ambient condition stable optically active phase material, characterised in that the material comprises a grid pattern of material alterations in metal halide perovskite material which material alterations separate metal halide perovskite material units.

By using an inventive system of present invention, it is possible to transform metal halide perovskite material into an at ambient condition stable optically active phase material. In order to enhance the formation of at ambient condition stable optically active phase material it is desirable to use this inventive method of manufacture.

The at ambient condition stable optically active phase material in an advantageous embodiment, characterised in that the area of grid pattern is on a surface of the metal halide perovskite material and the subsurface area thereunder; or it is characterised in that the pattern of material alterations in metal halide perovskite material are micron scale square blocks which comprise the unaltered metal halide perovskite material, or it is characterised in that the pattern of material alterations in metal halide perovskite material are barrels or cups; or it is characterised in that the pattern of material alterations in metal halide perovskite material have a tubular, cylindrical, discoidal, spherical, tabular, ellipsoidal, irregular or squared shape or it is characterised in that the pattern in metal halide perovskite material are upright partitions of material alterations so that an array of metal halide perovskite units separated by said partitions. Here by the alterations can be in any one of the following metal halide perovskite material comprising AMX3 compounds, whereby M is a metal ion such as Pb²⁺ and A is a cation such as methylammonium (MA+), formamidinium (FA+), cesium (Cs+), . . . and X is of the group consisting of fluoride (F⁻), chloride (Cl⁻), bromide (Br⁻), iodide (I⁻) and astatide (At⁻) and their mixed counterparts AmA′nA″(1−m−n)MXxX′yX″(3−x−y) MmM′nM″(1−m−n)AXxX′yX″(3−x−y) and doped counterparts with manganese, tin, magnesium, potassium, sodium, rubidium or silver or comprising perovskite with CsPbX3 (X=F, Cl, Br, I) compounds, or comprising perovskite with FAPbX3 (X=Cl, Br, I) compounds, comprising perovskite with CsPbI3, FAPbI3, MAPbI3 or their mixed compounds to manufacture stable optical/optoelectrical active CsPbI3 perovskite, FAPbI3 perovskite or their mixed perovskites, or comprising inorganic cations; or comprising organic cations or comprising a mixture of organic and inorganic cations or a combination thereof.

In one embodiment of the invention an at ambient condition stable optically active phase material is provided this material comprising a grid of walls of material alterations in the metal halide perovskite material whereby the wall are upright from a plane of the metal halide perovskite material that is proximate to a base carrier material to that plane of said the metal halide perovskite material that is distal from the base carrier material.

In another embodiment of the invention an at ambient condition stable optically active phase material is provided, whereby the walls of material alterations are sloped.

In yet another embodiment of the invention an at ambient condition stable optically active phase material is provided, characterised in that the material is in the form of a film.

In yet another embodiment of the invention an at ambient condition stable optically active phase material is provided, characterised in that the material has a shelf form, sheet form or a planar form.

In yet another embodiment of the invention an at ambient condition stable optically active phase material is provided, characterised in that the material is a layer stacked on a carrier layer.

In yet another embodiment of the invention an at ambient condition stable optically active phase material is provided, characterised in that the material is fitted on or annealed to a carrier layer for instance a glass layer or an indium tin oxide functionalized glass layer.

In yet another embodiment of the invention an at ambient condition stable optically active phase material is provided, characterised in that the material is spin coated on a substrate.

In an advantageous embodiment, the at ambient condition stable optically active phase material according to the present invention is comprised in or is a thin film.

In yet another advantageous embodiment, the at ambient condition stable optically active phase material according to the present invention is characterised in that the zones of material alteration on the material are at temperatures far below its phase transition temperature, for instance more than 50° C. thereunder, even more preferably more than 100° C. thereunder and yet more preferably more than 200° C. thereunder and when the metal halide perovskite material is CsPbI3 the zones of material alteration on the material can be at temperatures far below its phase transition temperature of 320 Celsius degree, for instance more than 50° C. thereunder, even more preferably more than 100° C. thereunder and yet more preferably more than 200° C. thereunder.

In yet another advantageous embodiment, the at ambient condition stable optically active phase material according to the present invention is with an area fixed or annealed with the area of a carrier material and whereby the pattern of material alterations comprised in the material forms array of partitions with upstanding walls formed by the grid of molecular material alterations in said the planar metal halide perovskite material and a bottom formed by the a plane of the planar metal halide perovskite material that is fixed or annealed to said the planar carrier material.

For the purposes of the present invention, the at ambient condition stable optically active phase material of present invention and/or obtained by the inventive method of manufacture can be used in optoelectronic devices of the group consisting of photovoltaics, light emitting, photo-detection, X-ray detection, Gamma-ray detection, imaging sensors, and chemical sensors.

### DETAILED DESCRIPTION

### Detailed Description of Embodiments of the Invention

The following detailed description of the invention refers to the accompanying drawings. The same reference numbers in different drawings identify the same or similar elements. Also, the following detailed description does not limit the invention. Instead, the scope of the invention is defined by the appended claims and equivalents thereof.

The following detailed description of the invention refers to the accompanying drawings. The same reference numbers in different drawings identify the same or similar elements. Also, the following detailed description does not limit the invention. Instead, the scope of the invention is defined by the appended claims and equivalents thereof.

Several documents are cited throughout the text of this specification. Each of the documents herein (including any manufacturer's specifications, instructions etc.) are hereby incorporated by reference; however, there is no admission that any document cited is indeed prior art of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn to scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to the devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Other embodiments of the invention will be apparent to those skilled in the art from consideration of the specification and practice of the invention disclosed herein.

It is intended that the specification and examples be considered as exemplary only.

Each and every claim is incorporated into the specification as an embodiment of the present invention. Thus, the claims are part of the description and are a further description and are in addition to the preferred embodiments of the present invention.

Each of the claims set out a particular embodiment of the invention.

The following terms are provided solely to aid in the understanding of the invention.

### Definitions

Particular and preferred aspects of the invention are set out in the accompanying independent and dependent claims. Features from the dependent claims may be combined with features of the independent claims and with features of other dependent claims as appropriate and not merely as explicitly set out in the claims.

“Ambient stable” is stable at ambient condition and/or in an ambient environment.

Present invention concerns a novel all-optical technique to stabilize the black phase of a halide perovskites AMX3, whereby M is a metal ion such as Pb²⁺ and A is a cation such as methylammonium (MA+), formamidinium (FA+), cesium (Cs+), . . . and X is of the group consisting of fluoride (F⁻), chloride (Cl⁻), bromide (Br⁻), iodide (I⁻) and astatide (At⁻) at temperatures below its phase transition temperature, for instance to stabilize the black phase of CsPbX (X=F, Cl, Br, I, At) or for instance to stabilize the black phase of FAPbX3 (X=F, Cl, Br, I, At). This stabilization can be carried out far below the phase transition temperature of the material, more than 50° C. thereunder, even more preferably more than 100° C. thereunder and yet more preferably more than 200° C. thereunder.

A particular embodiment concerns the all-optical technique to stabilize the black phase of a cesium lead iodide (CsPbX₃) at temperatures far below its phase transition temperature of 320 Celsius degree, for instance more than 50° C. thereunder, even more preferably more than 100° C. thereunder and yet more preferably more than 200° C. thereunder.

The method is fast, low cost and can be easily applied onto large-scale processing.

By this method of stabilization of present invention pattern grid structures is created by a laser beam onto an AMX3 material, whereby M is a metal ion such as Pb²⁺ and A is a cation such as methylammonium (MA+), formamidinium (FA+), cesium (Cs+), . . . and X is of the group consisting of fluoride (F⁻), chloride (Cl⁻), bromide (Br⁻), iodide (I⁻) and astatide (At⁻).

This method was particular found to be suitable to create such pattern grid structures onto cesium lead iodide combination for instance in CsPbI₃ whereby we could achieve such pattern grid structures of locoregional physical and chemical changes where a light beam regardless of wavelength illuminated.

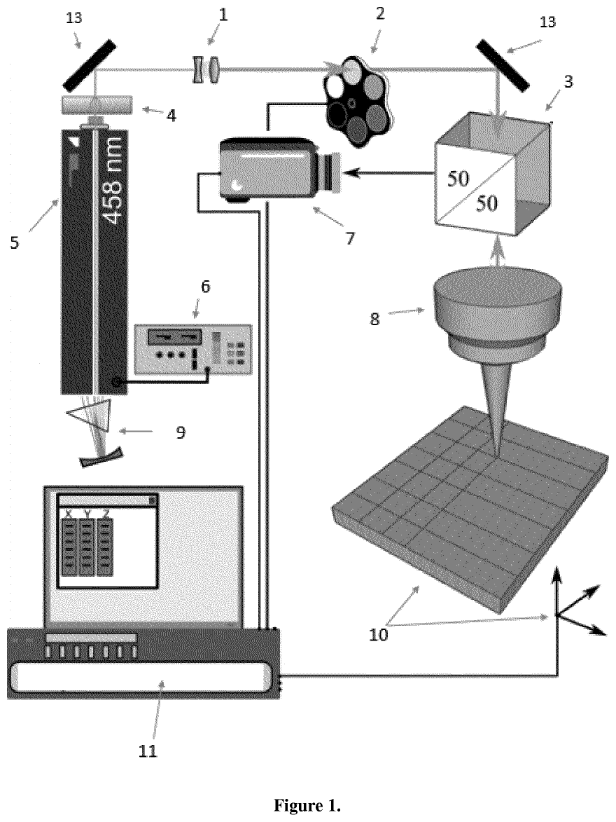

As shown in FIG. 1, the optically treated area or locoregional physicochemical modifications formed boundaries which acts to locally stabilize the phase of the material, greatly suppress the nucleation rate and slow down phase transition processes in the enclosed material region.

A thin film material that is optically processes by present invention and converted into its black phase, via thermal annealing, forms a stable black phase even after cooling to room temperature and this can last for weeks. This is in contrast to untreated thin film materials, which will only last in the order of 10s to minutes to several hours. Moreover, this method is reversible by optical or thermal treatments.

This technique enables stabilization of black phase inorganic perovskites for optoelectronic devices, including photovoltaics, light emitting, photo-detection, X-ray detection, Gamma-ray detection, imaging sensors, chemical sensors, etc.

### Example

The optical processing is performed using an optical beam, regardless of the wavelength, coherence, illumination area and polarization, to create connected patterns onto the perovskite thin film, atop a substrate like glass or ITO.

The optical patterning can be created by either a focused optical beam, structured illumination or by masked wide-file illumination. In an example, as shown in FIG. 1, a laser beam (458 nm wavelength) and a CsPbI₃ film prepared by the conventional film deposition method are used for demonstration.

The CsPbI3 solution was prepared by dissolving anhydrous CsI and PbI2 into anhydrous DMF. The typical concentration of CsPbI3 solution is 0.1-0.4 M. The CsPbI3 film was prepared by spincoating in a nitrogen glove box. Chlorobenzene was used as the antisolvent.

In a typical film deposition protocol, CsPbI3 solution filtered by a 0.45 um PTFE filter was dropped onto a clean glass slide, followed by spincoating at 1500 rpm for 30 s and 3000 rpm for 60 seconds. 30 seconds before the spincoating stopped, 100 uL of the antisolvent was injected quickly at the center of the film. The film was then transferred onto a hotplate for annealing at 160° C. for 60 seconds.

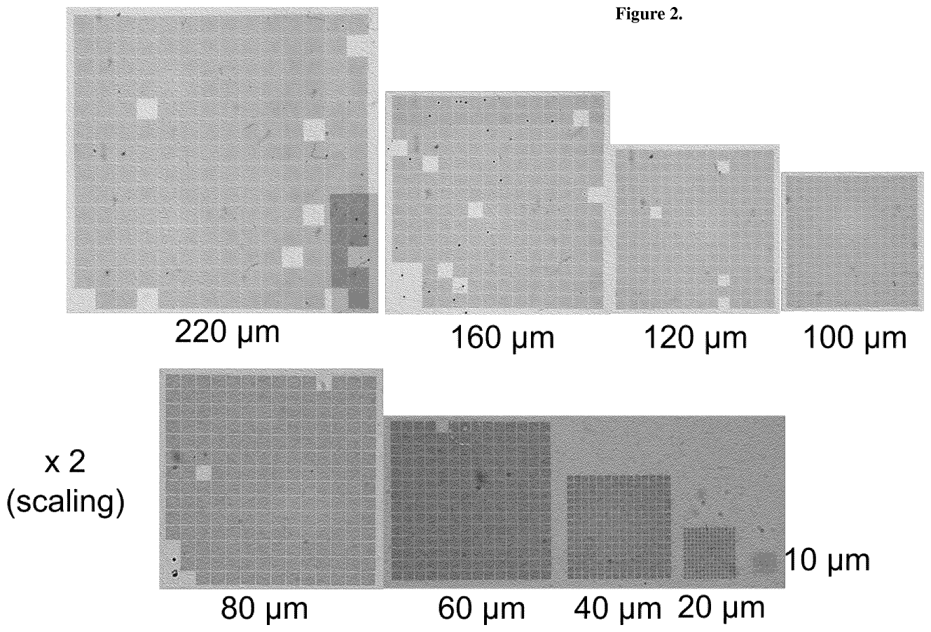

The optical beam (458 nm) in these examples is focused onto the perovskite film surface by an optical objective (10×, 0.4 NA). A motorized XYZ stage is used for precise sample positioning and for scanning the focused beam across the surface, forming the pattern. The power of the optical focal spot (20 mW) is controlled via a laser current supply module and a set of neutral-density filters and is monitored using a calibrated power meter (ThorLabs photodiode S130VC). Optical processing is then achieved by moving the substrate under the focused optical illumination using the XYZ stage. The optical patterning is defined by a series of XYZ coordinates controlled by a computer, permitting designs of different patterns. In the example, the perovskite thin film is patterned with square blocks ranging from 10×10 μm² to 220×220 μm² in dimension (FIG. 2). The substrate is then submitted to thermal treatments above the thermal phase transition (>320 Celsius degrees for CsPbI₃) to trigger the yellow-to-black phase transition. After rapid cooling back to room temperature (within a few minutes), the black phase of the materials remains within the patterned area. As shown in the transmission image in FIG. 2 (recorded 36 hours after thermal treatment and stored under ambient), the dark areas (highly light absorbing) represent the stabilized black phase perovskite, with the lighter portion of the image representing the part of the thin film which has returned to the yellow phase. The stabilizing effect is clearly present for all grid sizes presented in FIG. 2, a higher frequency of black phase stabilization appears to occur for smaller grid sizes.

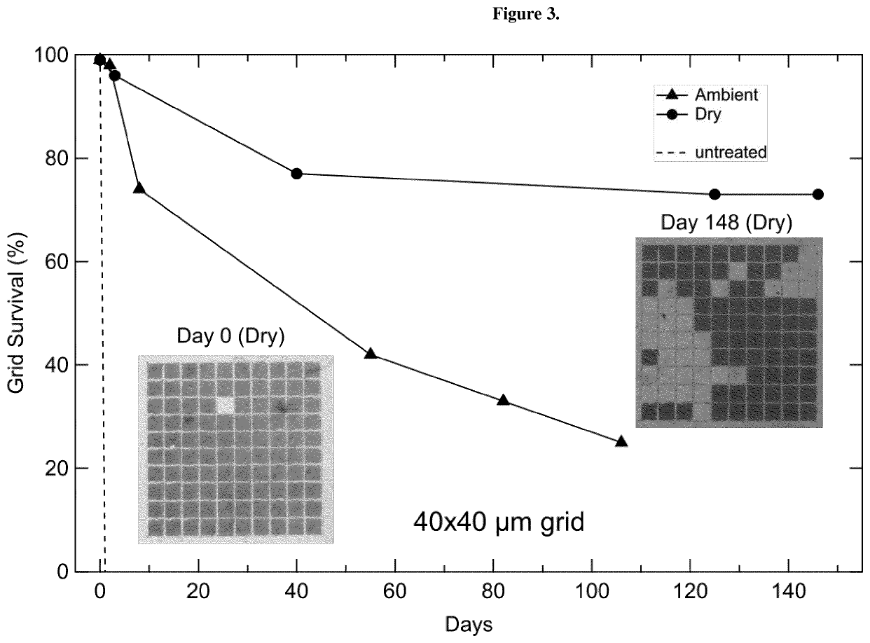

For the 40×40 μm2 grid size used for the stability test shown in FIG. 3, the sample exposed to ambient conditions and is found to be far more stable than the control film which was not subjected to the optical patterning before the thermal treatment. A further increase in the black phase stabilization can be achieved by protecting the film from the ambient moisture (dry sample in FIG. 3).

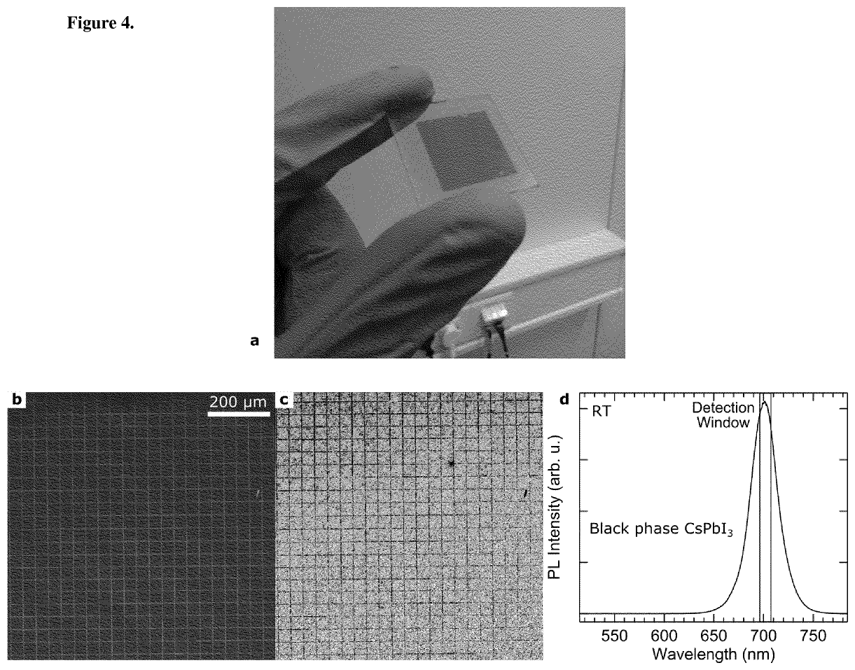

In FIGS. 4a and b, the 40×40 μm2 grid is patterned over a 2×2 cm2 area of a CsPbI₃ thin film. After 24 hours, the patterned area is found stable under ambient conditions and highly light absorbing and luminescent.

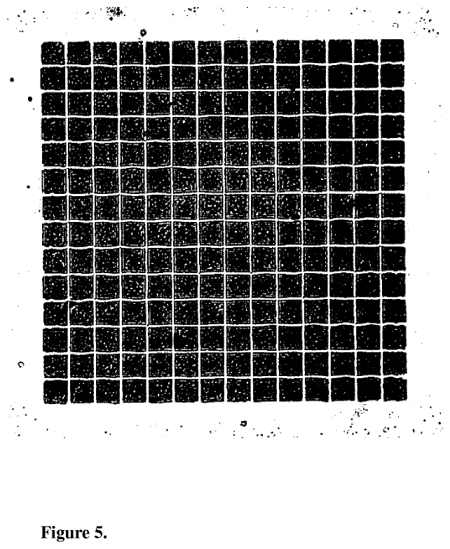

In FIG. 5, perovskite thin films prepared on indium tin oxide/glass substrates are found to also experience the same stabilizing influence of the optical patterning treatment.

Thus, the claims following the detailed description are hereby expressly incorporated into this detailed description, with each claim standing on its own as a separate embodiment of this invention.

### DRAWING DESCRIPTION

### Brief Description of the Drawings

The present invention will become more fully understood from the detailed description given herein below and the accompanying drawings which are given by way of illustration only, and thus are not limitative of the present invention, and wherein:

FIG. 1 Schematic diagram showing the optical processing, whereby focused light-induced patterns are introduced onto the thin film surface prior to thermal annealing. In FIG. 1a the following elements are displayed 1=beam expander, 2 is the ND filter, 3=the beam splitter, 4 is the bandpass filter, 5=the tunable Ar+ laser, 6 is the current controller, 7=the video camera, 8 is the objective, 9=the tuning prism, 10 is sample mounted on a XYZ translation stage, 11 is the computer with the processor and acquisition software and 13=a mirror.

FIG. 2 Optical transmission images of optically treated 14×14 boxes of varying square size patterns (10×10 μm2, 20×20 μm2, 40×40 μm2, 60×60 μm2, 80×80 μm2, 100×100 μm2, 120×120 μm2, 160×160 μm2, 220×220 μm2) recorded 24 hours after thermal annealing. The smaller patterns at the lower row are magnified 2× with respect to the patterns in the upper row.

FIG. 3 Survival of 40×40 μm2 square optically treated grid areas over time under both ambient and dry atmospheres, compared to the untreated film under ambient conditions (dashed line). The symbol ▴ means ambient and the symbol ● means dry.

FIG. 4 (a) optical image of an optically treated perovskite film on a glass substrate, area consisting of 40×40 μm2 grids covering a 2×2 cm² area. The dark central region was optically treated. (b) Dark field image of this film from using λ_{exc}=488 nm, where there the absorbed light is the black phase perovskite stabilized by the optical treatment. (c) The glowing emission of the black phase perovskite across the corresponding film in (b) recorded at 488 nm excitation and detecting the emission around 700 nm as indicated in (d), (d) Emission spectra corresponding to an emission of the room-temperature black phase CsPbI₃ material (producing the image in (c)), stabilized through the laser optical treatment. The detection window used to record (c) is indicated.

FIG. 5 Optical transmission images of optically treated 14×14 boxes of 40×40 μm2 recorded 24 hours after thermal annealing. The perovskite film was deposited on the ITO layer of an ITO/glass slide.

1-81. (canceled)

82. A method of manufacturing an optically active perovskite phase material that is stable at ambient environment, the method comprising subjecting an area of a metal halide perovskite material to an irradiation treatment.

83. The method of claim 82, wherein the irradiation treatment comprises irradiating the area of the metal halide perovskite material locoregionally and in a grid pattern.

84. The method of the claim 82, wherein the irradiation treatment creates a pattern as micron scale square blocks.

85. The method of claim 82, wherein the irradiation treatment comprises grafting a grid pattern of barrels or cups in the area of the metal halide perovskite material.

86. The method of claim 85, wherein the barrels or cups have a cubic, tubular, cylindrical, discoidal, spherical, tabular, ellipsoidal, irregular, or squared shape.

87. The method of claim 82, wherein the irradiation treatment is a masked illumination.

88. The method of claim 82, wherein the irradiation treatment is a masked illumination of the material through a mask pattern by which certain locoregions on the material are illuminated and other regions are not illuminated.

89. An optically active perovskite phase material that is stable at ambient condition, the optically active perovskite phase material comprising a metal halide perovskite material with a grid pattern of material alterations in the metal halide perovskite material.

90. The optically active perovskite phase material of claim 89, wherein the material alterations separate metal halide perovskite material units.

91. The optically active perovskite phase material of claim 89, wherein the grid pattern of material alterations in the metal halide perovskite material are barrels or cups.

92. The optically active perovskite phase material of claim 89, wherein the pattern of material alterations in metal halide perovskite material have a tubular, cylindrical, discoidal, spherical, tabular, ellipsoidal, irregular, or squared shape.

93. The optically active perovskite phase material of claim 89, wherein the metal halide perovskite material is selected from:
(a) compounds AMX₃,
(b) mixed compounds AₘA′ₙA″₍₁₋ₘ₋ₙ₎MXₓX′_{y}X″_{(3-x-y)},
(c) mixed compounds MₘM′ₙM″₍₁₋ₘ₋ₙ₎AXₓX′_{y}X″_{(3-x-y)}, and
(d) compounds according to (a), (b), or (c) that are doped with manganese, tin, magnesium, potassium, sodium, rubidium, or silver,
where:
A, A′, and A″ are independently chosen monovalent cations;
M, M′, and M″ are independently chosen divalent metal ions;
X, X′, and X″ are independently selected from the group consisting of fluoride (F⁻), chloride (Cl⁻), bromide (Br⁻), iodide (I⁻) and astatide (At⁻);
m and n are independently from 0 to 1;
m+n=1;
x and y are independently from 0 to 3; and
x+y=3.

94. The optically active perovskite phase material of claim 93, wherein:
A, A′, and A″ are independently chosen from methylammonium (MA), formamidinium (FA⁺), and cesium (Cs⁺); and
M, M′, and M″ are Pb²⁺.

95. The optically active perovskite phase material of claim 89, wherein the metal halide perovskite material comprises a compound CsPbX₃, where each X is F, Cl, Br, or I.

96. The optically active perovskite phase material of claim 89, wherein the metal halide perovskite material comprises a compound FAPbX₃, where FA is formamidium and each X is Cl, Br, or I.

97. The optically active perovskite phase material of claim 89, wherein the material alterations on the metal halide perovskite material are applied at temperatures more than 50° C. below the phase transition temperature of the metal halide perovskite material.

98. The optically active perovskite phase material of claim 89, wherein the material alterations are chemical alterations or physical alterations.
